(19) United States
(12) Patent Application Publication
(10) Pub. No.: US 2018/0292719 A1
(43) Pub. Date: Oct. 11, 2018

(54) ARRAY SUBSTRATE AND LIQUID CRYSTAL DISPLAY PANEL COMPRISING THE SAME

(71) Applicant: WUHAN CHINA STAR OPTOELECTRONICS TECHNOLOGY CO., LTD., Wuhan, Hubei (CN)

(72) Inventor: Xiaojiang YU, Wuhan, Hubei (CN)

(21) Appl. No.: 15/522,563

(22) PCT Filed: Mar. 14, 2017
(86) PCT No.: PCT/CN2017/076554

§ 371 Date: Apr. 27, 2017

(30) Foreign Application Priority Data
Feb. 24, 2017 (CN) 201710102380.3

(51) Int. Cl. G02F 1/1362; H01L 27/02; H01L 27/12

(52) U.S. Cl. CPC G02F 1/136204; G02F 1/136286; G02F 2202/22; H01L 27/1244; G02F 2202/104; H01L 27/0296

(57) ABSTRACT

Disclosed is an array substrate and a liquid crystal display panel including the array substrate. The array substrate includes: a dummy pixel region, a display region, and a drive circuit region, wherein the dummy pixel region is located between the display region and the drive circuit region, both of the display region and the dummy pixel region being provided with a plurality of poly-silicon wires and a plurality of gate lines, the poly-silicon wires and the gate lines crossing each other in different layers. An overlapping area between the poly-silicon wires and the gate lines in the dummy pixel region is larger than an overlapping area between the poly-silicon wires and the gate lines in the display region. The array substrate is capable of effectively discharging an electrostatic voltage and significantly weakening the electrostatic voltage that may continue to be introduced into the display region along the gate lines, so as to prevent damage to the function of pixels in the display region.

### CROSS-REFERENCE TO RELATED APPLICATIONS

The present application claims the priority of Chinese patent application CN 2017101023803, entitled “Array substrate and liquid crystal display panel comprising the same” and filed on Feb. 24, 2017, the entirety of which is incorporated herein by reference.

### FIELD OF THE INVENTION

The present disclosure relates to the field of electrical protection, and particularly, to an array substrate capable of effectively discharging electrostatic voltage, and a liquid crystal display panel comprising the array substrate.

### BACKGROUND OF THE INVENTION

In manufacturing procedures or operations of a liquid crystal display panel device within specific voltage, current, and power limit ranges, a large number of accumulated electrostatic charges will be subject to high-voltage discharge under appropriate conditions. High-voltage instantaneous transmission of electrostatic discharge (ESD) through a circuit device leading wire may break down an insulation layer of the circuit device, thereby resulting in function loss of the circuit device. When the low-temperature poly-silicon (LTPS) technology is used in the display panel, due to the introduction of TFT modules, digital signals will work at a higher frequency, thereby increasing probability of electrostatic discharge events occurring in the circuit device. In a structure design of a low-temperature poly-silicon array, a drive circuit region (GOA) capable of providing a gate drive signal for a display region often contains a large area of metal, and is therefore susceptible to electrostatic discharge events, resulting in a large electrostatic voltage. The electrostatic voltage of the drive circuit region can be introduced into the display region along a gate line, causing damage to pixels in the display region at an edge thereof adjacent to the drive circuit region.

In the prior art, the purpose of electrostatic protection is usually achieved by a procedure of arranging a dummy pixel region at the edge of the display region. The principle of this procedure is to render the electrostatic voltage in the dummy pixel region fully discharged, thereby preventing a high electrostatic voltage from continuing to be transmitted into the display region to break down the pixels in the display region.

For example, FIG. 1 shows a partial detail view of an existing array substrate, which mainly includes a dummy pixel region 1′, a source line 2′, a gate line 3′, a poly-silicon wire 4′, a pixel ITO wire 5′, a display region 6′, and a drive circuit region 7′. In the array substrate as shown in FIG. 1, the dummy pixel region 1′ is located at an edge of the display region 6′, i.e., between the display region 6′ and the drive circuit region 7′. The source line 2′ is perpendicular to the gate line 3′ in different planes. The poly-silicon wire 4′ and the gate line 3′ cross each other in different layers, and the poly-silicon wire 4′ is connected to the source line 2′ by means of a via hole (not shown in the drawing). In a manufacturing procedure of the array substrate, before an ESD high voltage generated in the drive circuit region 7′ is introduced into the display region 6′ along the gate line 3′, since the gate line 3′ and the poly-silicon wire 4′ in the dummy pixel region 1′ cross each other in different layers only twice (the gate line 3′ and the poly-silicon wire 4′ are separated by only about a 100 nm thick gate insulation layer, which can be easily broken down by a high voltage difference between the gate line 3′ and the poly-silicon wire 4′), an overlapping area is very limited, such that non-discharged electrostatic high voltage continues to be introduced into the display region 6′ to break down the pixels therein, thereby causing abnormal highlight or dark spots at the edge of the display region 6′.

In other words, the inventor of the present disclosure has found that the electrostatic voltage cannot be discharged effectively when the overlapping area between the poly-silicon wire 4′ and the gate line 3′ in the dummy pixel region 1′ is equal to or smaller than an overlapping area between the poly-silicon wire 4′ and the gate line 3′ in the display region 6′. Therefore, when the electrostatic voltage is too large to be fully discharged in the dummy pixel region, the electrostatic voltage will continue to be introduced into the display region along the gate line, thereby damaging pixel functions in the display region.

### SUMMARY OF THE INVENTION

The purpose of the present disclosure is to provide an array substrate and a liquid crystal display panel comprising the array substrate capable of effectively discharging electrostatic voltage, thereby remarkably weakening the electrostatic voltage that may continue to enter a display region along a gate line, and preventing a pixel function of the display region from being damaged.

In order to achieve the above purpose, the present disclosure provides an array substrate, comprising: a dummy pixel region, a display region, and a drive circuit region, wherein the dummy pixel region is located between the display region and the drive circuit region, both of the display region and the dummy pixel region being provided with a plurality of poly-silicon wires a plurality of gate lines, the poly-silicon wires and the gates lines crossing each other in different layers,

wherein an overlapping area between the poly-silicon wires and the gate lines in the dummy pixel region is larger than an overlapping area between the poly-silicon wires and the gate lines in the display region.

In the array substrate, the poly-silicon wires and the gate lines cross each other in different layers at least three times in the dummy pixel region.

In the array substrate, the poly-silicon wires and the gate lines cross each other in different layers seven times in the dummy pixel region.

In the array substrate, the poly-silicon wires crossing the gate lines in a different layer in the dummy pixel region are in parallel connection with each other.

In the array substrate, the poly-silicon wires crossing the gate lines in a different layer in the dummy pixel region are in series connection with each other.

In the array substrate, a line width of the poly-silicon wire within the dummy pixel region is greater than a line width of the poly-silicon wire within the display region.

In the array substrate, a line width of the gate line in the dummy pixel region is greater than a line width of the gate line in the display region.

In the array substrate, a transition region is further provided between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

In the array substrate, the transition region is a dummy pixel region or a display region.

The present disclosure further provides a liquid crystal display panel, comprising the above array substrate.

In view of the above, the advantageous effects of the present disclosure are as follows.

At the outset, the overlapping area between the poly-silicon wires and the gate lines in the dummy pixel region is rendered larger than the overlapping area between the poly-silicon wires and the gate lines in the display region, such that the electrostatic voltage can be effectively discharged from the dummy pixel region, thereby preventing pixels in the display region from being broken down, thus to improve the manufacturing yield of the display panel.

In addition, the transition region, which may be either a dummy pixel region or a display region, is provided between the dummy pixel region and the display region. The overlapping area between the poly-silicon wires and the gate lines in the transition region may be smaller than or equal to the overlapping area between the poly-silicon wires and the gate lines within the dummy pixel region, and the overlapping area between the poly-silicon wires and the gate lines within the transition region may be greater than or equal to the overlapping area between the poly-silicon wires and the gate lines within the display region. This enables further discharge of the electrostatic voltage and improves the electrostatic protection of the display region.

### BRIEF DESCRIPTION OF THE DRAWINGS

The present disclosure will be explained in more detail with reference to embodiments and accompanying drawings, in which:

FIG. 1 is a partial detail view of an existing array substrate;

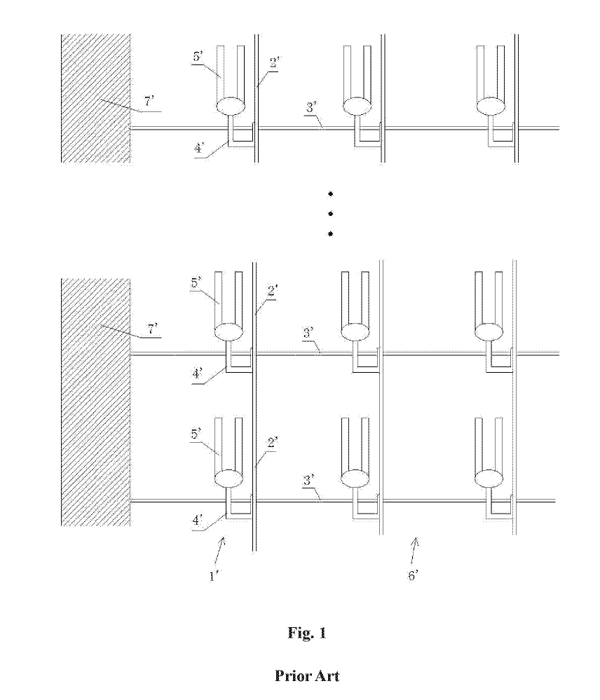

FIG. 2 is a partial detail view of one preferred embodiment of an array substrate according to the present disclosure; and

FIG. 3 is a partial detail view of another preferred embodiment of the array substrate according to the present disclosure.

In the accompanying drawings, the same components are indicated by the same reference signs. The accompanying drawings are not drawn to actual scale.

### DETAILED DESCRIPTION OF THE EMBODIMENTS

The present disclosure will now be further described with reference to the accompanying drawings.

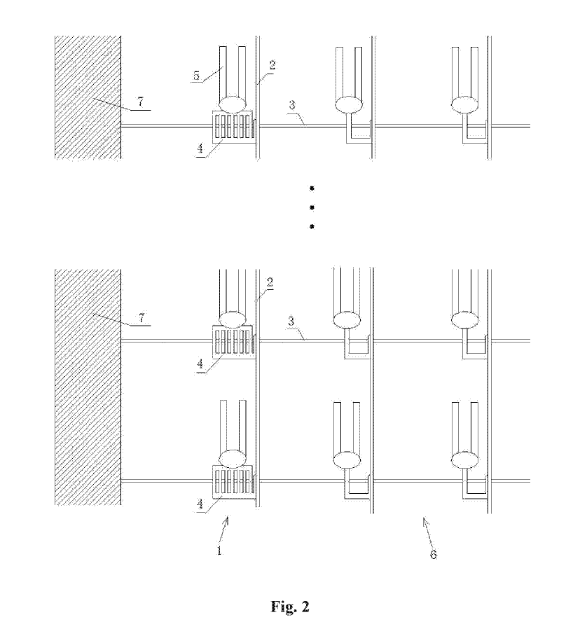

FIG. 2 shows a partial detail view of one preferred embodiment of an array substrate according to the present disclosure. The array substrate mainly includes a dummy pixel region 1, a source line 2, a gate line 3, a poly-silicon wire 4, a pixel ITO wire 5, a display region 6, and a drive circuit region 7, wherein the dummy pixel region 1 is located at an edge of the display region 6, i.e., between the display region 6 and the drive circuit region 7. The display region 6 and the dummy pixel region 1 are both provided therein with the source lines 2, the gate lines 3, the poly-silicon wires 4, and the pixel ITO wires 5. The source lines 2 are perpendicular to the gate lines 3 in different planes, and the poly-silicon wires 4 and the gate lines 3 cross each other in different layers. The poly-silicon wires 4 are connected to the source lines 2 through via holes (not shown).

The improvement of the present disclosure is such that an overlapping area between the poly-silicon wires 4 and the gate lines 3 in the dummy pixel region 1 is larger than an overlapping area between the poly-silicon wires 4 and the gate lines 3 in the display region 6. Thus, an electrostatic voltage can be effectively discharged, to prevent pixels in the display region 6 from being broken, thereby improving the manufacturing yield of a display panel.

Specifically, in the dummy pixel region 1, the poly-silicon wires 4 and the gate lines 3 cross each other in different layers at least three times, so that the overlapping area between the poly-silicon wires and the gate lines 3 within the dummy pixel region 1 is 50% greater than the overlapping area between the poly-silicon wires 4 and the gate lines 3 within the display region, thereby increasing capacitance between the poly-silicon wires 4 and the gate lines 3. This enables the electrostatic voltage to be discharged from the dummy pixel region 1, so as to perform electrostatic protection on the display region 6.

More specifically, the poly-silicon wires 4 and the gate lines 3 shown in FIG. 2 cross each other in different layers seven times, so that the overlapping area between the poly-silicon wires 4 and the gate lines 3 within the dummy pixel region 1 is obviously three times greater than the overlapping area between the poly-silicon wires 4 and the gate lines 3 within the display region. As a result, the electrostatic voltage can be sufficiently discharged, so as to prevent the pixels in the display region 6 from being broken. It should be noted that the number of times the poly-silicon wires 4 and the gate lines 3 crossing each other in different layers is not limited to the above-described embodiment, and may be four times, five times, six times, eight times, and so on.

Preferably, in the dummy pixel region 1, the poly-silicon wires 4 crossing the gate lines 3 in a different layer are connected in parallel, to facilitate processing and effective control of production costs. Of course, the poly-silicon wires 4 crossing the gate lines 3 in a different layer may also be connected in series.

Of course, the present disclosure does not intend to limit a shape or a connection manner of the poly-silicon wires 4, which may be in any regular or irregular shape, as long as it can be ensured that the overlapping area between the poly-silicon wires 4 and the gate lines 3 within the dummy pixel region 1 is greater than the overlapping area between the poly-silicon wires 4 and the gate line 3 in the display region 6.

For example, in the dummy pixel region 1, the poly-silicon wires 4 are in a bold design in overlapping portions with the gate lines 3, and the gate lines 3 may also be in a bold design in the overlapping portions. In other words, a line width of the poly-silicon wires 4 in the dummy pixel region 1 is rendered larger than a line width of the poly-silicon wires 4 in the display region 6, and/or a line width of the gate lines 3 in the dummy pixel region 1 is rendered larger than a line width of the gate lines 3 in the display region 6. The overlapping area between the poly-silicon wires 4 and the gate lines 3 in the dummy pixel region 1 can thus be increased, so as to increase the capacitance therebetween, thereby effectively discharging the electrostatic voltage.

The poly-silicon wires 4 are obtained through patterning of a poly-silicon layer. This does not increase any step as compared with a manufacturing procedure of existing poly-silicon wires. Thus, electrostatic protection of the display region can be achieved without increasing the costs. Specifically, a poly-silicon wire unit 1 may be prepared by a procedure comprising film deposition, exposure, and etching, but is not limited thereto.

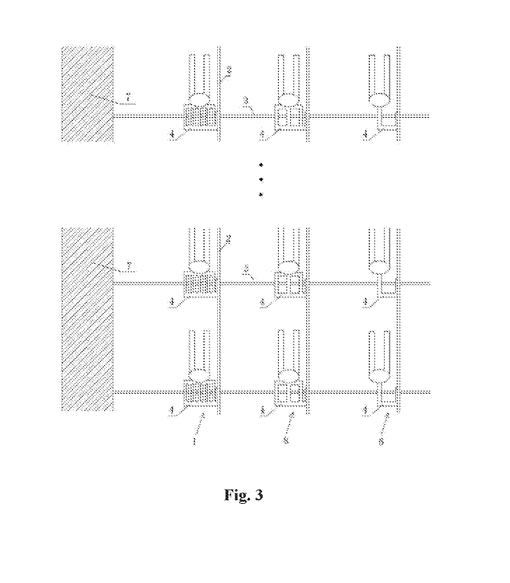

FIG. 3 shows a partial detail view of another preferred embodiment of the array substrate according to the present disclosure. This embodiment differs from the previous embodiment in that a transition region 8, which may be either a dummy pixel region or a display region, is further provided between the dummy pixel region 1 and the display region 6.

An overlapping area between the poly-silicon wires 4 and the gate lines 3 within the transition region 8 may be smaller than or equal to the overlapping area between the poly-silicon wires 4 and the gate lines 3 within the dummy pixel region 1, and the overlapping area between the poly-silicon wires 4 and the gate lines 3 within the transition region 8 may be greater than or equal to an overlapping area between the poly-silicon wires 4 and the gate lines 3 within the display region 6.

In this way, when the transition region 8 is a dummy pixel region, if a first column of dummy pixel regions (referred to as “1” in the figure) in FIG. 3 has not sufficiently discharged the electrostatic voltage, a second column of dummy pixel regions (referred to as “8” in the figure) will continue to discharge the electrostatic voltage, so as to ensure that a gate insulation layer in the display region will not be broken down when the voltage continues to be loaded in the display region 6.

When the transition region 8 is a display region, if the dummy pixel region (referred to as “1” in the figure) in FIG. 3 has not sufficiently discharged the electrostatic voltage, the edge of the display region (referred to as “8” in the figure) will continue to discharge the electrostatic voltage, so as to ensure that the gate insulation layer in the display region will not be broken down when the voltage continues to be loaded in a manner gradually approaching a middle position of the display region 6.

This design is performed out of the following considerations. On the one hand, when the display region is used, an electrostatic voltage generated thereby should be discharged with an electrostatic protection device. On the other hand, an electrostatic voltage generated in a manufacturing procedure of a liquid crystal display panel is transmitted from the drive circuit region to the display region, during which the voltage is gradually consumed. That is, the voltage is larger at the edge of the display region and smaller close to a central part of the display region. Hence, when the structure of the liquid crystal panel is designed, the number of gate poly-silicon wires in the poly-silicon wire unit at the edge of the display region is designed to be greater than or equal to the number of gate poly-silicon wires in the poly-silicon wire unit near the central part of the display region. It should be noted that since the transition region 8 is located at the edge of the display region, it will not negatively affect an imaging effect of the display region 6.

In addition, as shown in FIG. 3, the dummy pixel regions 1 and the transition regions 8 are designed in respective columns, and countless columns of display regions can be provided. In an actual production process, however, appropriate columns of pixels in the dummy pixel region, the transition region, and the display regions may be provided in accordance with structural requirements and production conditions of the liquid crystal display panel to be produced. Optimal poly-silicon wire structures in different regions can be obtained according to specific production procedures, tooling conditions, and use conditions of the liquid crystal display panel.

The present disclosure further provides a liquid crystal display panel, comprising the array substrate in any one of the above structures.

In view of the above, the advantageous effects of the present disclosure are as follows.

At the outset, the overlapping area between the poly-silicon wires and the gate lines in the dummy pixel region is rendered larger than the overlapping area between the poly-silicon wires and the gate lines in the display region, such that the electrostatic voltage can be effectively discharged from the dummy pixel region, thereby preventing pixels in the display region from being broken down, thus to improve the manufacturing yield of the display panel.

In addition, the transition region, which may be either a dummy pixel region or a display region, is provided between the dummy pixel region and the display region. The overlapping area between the poly-silicon wires and the gate lines in the transition region may be smaller than or equal to the overlapping area between the poly-silicon wires and the gate lines within the dummy pixel region, and the overlapping area between the poly-silicon wires and the gate lines within the transition region may be greater than or equal to the overlapping area between the poly-silicon wires and the gate lines within the display region. This enables further discharge of the electrostatic voltage and improves the electrostatic protection of the display region.

Although the present disclosure has been described with reference to preferred embodiments, various modifications and variants to the present disclosure may be made by anyone skilled in the art, without departing from the scope and spirit of the present disclosure. In particular, as long as there is no structural conflict, various embodiments as well as the respective technical features mentioned herein may be combined with one another in any manner. The present disclosure is not limited to the specific examples disclosed herein, but rather includes all the technical solutions falling within the scope of the claims.

1. An array substrate, comprising: a dummy pixel region, a display region, and a drive circuit region, wherein the dummy pixel region is located between the display region and the drive circuit region, both of the display region and the dummy pixel region being provided with a plurality of poly-silicon wires and a plurality of gate lines, the poly-silicon wires and the gate lines crossing each other in different layers,
wherein an overlapping area between the poly-silicon wires and the gate lines in the dummy pixel region is larger than an overlapping area between the poly-silicon wires and the gate lines in the display region.

2. The array substrate according to claim 1, wherein the poly-silicon wires and the gate lines cross each other in different layers at least three times in the dummy pixel region.

3. The array substrate according to claim 1, wherein the poly-silicon wires and the gate lines cross each other in different layers seven times in the dummy pixel region.

4. The array substrate according to claim 1, wherein the poly-silicon wires crossing the gate lines in a different layer in the dummy pixel region are in parallel connection with each other.

5. The array substrate according to claim 1, wherein the poly-silicon wires crossing the gate lines in a different layer in the dummy pixel region are in series connection with each other.

6. The array substrate according to claim 1, wherein a line width of the poly-silicon wire within the dummy pixel region is greater than a line width of the poly-silicon wire within the display region.

7. The array substrate according to claim 1, wherein a line width of the gate line in the dummy pixel region is greater than a line width of the gate line in the display region.

8. The array substrate according to claim 1, wherein the array substrate further comprises a transition region, and the transition region is between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

9. The array substrate according to claim 2, wherein the array substrate further comprises a transition region, and the transition region is between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

10. The array substrate according to claim 3, wherein the array substrate further comprises a transition region, and the transition region is between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

11. The array substrate according to claim 4, wherein the array substrate further comprises a transition region, and the transition region is between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

12. The array substrate according to claim 5, wherein the array substrate further comprises a transition region, and the transition region is between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

13. The array substrate according to claim 6, wherein the array substrate further comprises a transition region, and the transition region is between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

14. The array substrate according to claim 7, wherein the array substrate further comprises a transition region, and the transition region is between the dummy pixel region and the display region, an overlapping area between the poly-silicon wires and the gate lines within the transition region being smaller than or equal to the overlapping area between the poly-silicon wires and the gate lines in the dummy pixel region, and the overlapping area between the poly-silicon wires and the gate lines in the transition region being greater than or equal to the overlapping area between the poly-silicon wires and the gate lines in the display region.

15. The array substrate according to claim 8, wherein the transition region is a dummy pixel region or a display region.

16. The array substrate according to claim 9, wherein the transition region is a dummy pixel region or a display region.

17. The array substrate according to claim 10, wherein the transition region is a dummy pixel region or a display region.

18. The array substrate according to claim 11, wherein the transition region is a dummy pixel region or a display region.

19. The array substrate according to claim 12, wherein the transition region is a dummy pixel region or a display region.

20. A liquid crystal display panel, comprising the array substrate according to claim 1.
